(19) United States
(12) Patent Application Publication
(10) Pub. No.: US 2025/0048803 A1
(43) Pub. Date: Feb. 6, 2025

(54) LIGHT EMITTING APPARATUS

(71) Applicant: Seoul Semiconductor Co., Ltd., Ansan-si (KR)

(72) Inventors: Kwang Bea LIM, Ansan-si (KR); Bo Ram I JANG, Ansan-si (KR)

(73) Assignee: Seoul Semiconductor Co., Ltd., Ansan-si (KR)

(21) Appl. No.: 18/792,636

(22) Filed: Aug. 2, 2024

Related U.S. Application Data
(60) Provisional application No. 63/618,426, filed on Jan. 8, 2024.
(60) Provisional application No. 63/530,818, filed on Aug. 4, 2023.

(51) Int. Cl. H01L 33/50; G02F 1/13357; H01L 25/075

(52) U.S. Cl. CPC H01L 33/504; G02F 1/133603; H01L 25/0753

(57) ABSTRACT

A light emitting apparatus is disclosed. The light emitting apparatus includes a substrate and a light emitting region disposed on the substrate and including a first light emitter and a second light emitter. The light emitted from the first light emitter has a first spectrum, light emitted from the second light emitter has a second spectrum, The first light emitter includes a first light emitting device emitting light having a first peak wavelength and a first wavelength converter emitting a first light. The second light emitter includes a second light emitting device emitting the second spectrum. The first spectrum and the second spectrum has at least one different peak wavelength. and The light of the light emitting region has a third spectrum that is mixture of the first spectrum and the second spectrum.

### CROSS REFERENCE TO RELATED APPLICATIONS

The present application is a Non-provisional Application which claims priority to the benefit of U.S. Provisional Application Nos. 63/530,818 filed Aug. 4, 2023, and 63/618,426 filed Jan. 8, 2024, shich are hereby incorparated by reference for all purposes as if fully set forth herein.

### BACKGROUND

### Field

Embodiments of the present disclosure relate to a light emitting apparatus.

### Discussion of the Background

A light emitting diode is an inorganic semiconductor device that emits light generated by recombination of electrons and holes. In recent years, light emitting diodes have been used in a variety of applications including display devices, automotive lamps, and general lighting. Light emitting diodes have various advantages of long lifespan, low power consumption, and fast response time. With these advantages, the light emitting diodes are rapidly replacing traditional light sources.

### SUMMARY

Embodiments of the present disclosure provide a light emitting apparatus with an improved color rendering index (CRI).

Embodiments of the present disclosure provide a light emitting apparatus that has an improved color rendering index and reduces manufacturing costs.

Embodiments of the present disclosure provide a light emitting apparatus that has a broad color gamut to improve color reproduction.

Embodiments of the present disclosure provide a light emitting apparatus with improved reliability.

Embodiments of the present disclosure provide a light emitting apparatus that has improved light extraction efficiency to improve luminous efficacy.

Embodiments of the present disclosure provide a light emitting apparatus that is stable to temperature change by solving a problem of difference between a ratio of a blue light, a red light, or a green light and a preset ratio due to problems, such as degradation of the light emitting apparatus and the like.

Embodiments of the present disclosure provide a light emitting apparatus that reduce manufacturing costs through reduction in content of phosphors.

Embodiments of the present disclosure provide a light emitting apparatus manufactured in a small size.

In accordance with one aspect of the present disclosure, there is provided a light emitting apparatus including a substrate, a light emitting region including a first light emitter, and a second light emitter. The first light emitter is formed on the substrate and emits a first light having a first spectrum. The second light emitter is formed on the substrate and emits a second spectrum. The first light emitter includes a first light emitting device emitting light having a first peak wavelength and a first wavelength converter emitting first excitation light. The second light emitter includes a second light emitting device emitting the second spectrum. The first wavelength converter includes a first light transmitting layer formed of a light transmitting material and covering the first light emitting device and at least a type of wavelength conversion material. Each of the first spectrum and the second spectrum has at least one different peak wavelength.

Accordingly, the light emitting region may emit a third light having a third spectrum that is a mixture of the first spectrum and the second spectrum.

The first spectrum may have peak wavelengths in a blue wavelength band and a red wavelength band, respectively. In addition, the second spectrum may have peak wavelengths in a blue wavelength band and a green wavelength band, respectively.

The third spectrum may have peak wavelengths in a blue wavelength band, a green wavelength band, and a red wavelength band, respectively.

The first wavelength converter may include: a first wavelength conversion material emitting light having a second peak wavelength; and a second wavelength conversion material emitting a first red light.

At least a portion of each of the first wavelength conversion material and the second wavelength conversion material may be dispersed in a different region of the first light transmitting layer.

The third spectrum may have a luminous intensity of a peak wavelength in the green wavelength band that is 40% or more of a luminous intensity of a peak wavelength in the red wavelength band.

The third spectrum may have a difference of 3% or more in luminous intensity between the peak wavelength and a valley wavelength in the green wavelength band.

The third spectrum may have a higher color rendering index than the first spectrum and the second spectrum.

The first wavelength converter may further include a third wavelength conversion material emitting a second red light. The second red light may have a narrower full width at half maximum than the first red light.

At least a portion of the third wavelength conversion material may be dispersed in a region different from a region in which at least a of the first wavelength conversion material or the second wavelength conversion material is dispersed.

The light emitting apparatus may further include a second light transmitting layer covering both the first light emitter and the second light emitting device and allowing light to transmit therethrough.

The light emitting apparatus may further include a second wavelength converter including a second light transmitting layer and a third wavelength conversion material dispersed in the second light transmitting layer and emitting a second red light. The second red light may have a narrower full width at half maximum than the first red light.

The second light emitter may further include a second light transmitting layer covering the second light emitting device and allowing light to transmit therethrough.

The second light emitter may further include a second wavelength converter including the second light transmitting layer and a third wavelength conversion material dispersed in the second light transmitting layer and emitting a second red light. The second red light may have a narrower full width at half maximum than the first red light.

A color rendering index (Ra) of the third spectrum may be higher than color rendering indexes of the first spectrum and the second spectrum.

In accordance with another aspect of the present disclosure, there is provided a light emitting apparatus including a substrate and a light emitting region including a first light emitter, a second light emitter. The first light emitter emits a first light having a first spectrum and includes at least a first light emitting device emitting light having a first peak wavelength and a first wavelength converter. The second light emitter includes at least a second light emitting device emitting a second light having a second spectrum. The first light emitter and the second light emitter are mounted on a substrate. The substrate includes a drive device or a drive circuit controlling drive power of the first light emitter and the second light emitter. The first wavelength converter includes a first light transmitting layer formed of a light transmitting material and covering the first light emitting device and at least a type of wavelength conversion material. Each of the first spectrum and the second spectrum has at least one different peak wavelength.

Accordingly, the light emitting region may emit a third light having a third spectrum that is a mixture of the first spectrum and the second spectrum. In addition, a color rendering index (Ra) of the third spectrum is higher than color rendering indexes of the first spectrum and the second spectrum.

The first wavelength converter may include a first wavelength conversion material emitting light having a second peak wavelength and a second wavelength conversion material emitting a first red light.

The first wavelength converter may further include a third wavelength conversion material emitting a second red light. The second red light may have a narrower full width at half maximum than the first red light.

The light emitting apparatus may further include a second light transmitting layer covering the second light emitting device or covering both the first light emitter and the second light emitting device, and a third wavelength conversion material dispersed in the second light transmitting layer. The third wavelength conversion material emits a second red light. The second red light has a narrower full width at half maximum than the first red light.

In accordance with a further aspect of the present disclosure, there is provided a backlight unit including a light emitting apparatus, optical sheets disposed on the light emitting apparatus, and a lower cover receiving the light emitting apparatus and the optical sheets therein. The light emitting apparatus includes a substrate, at least a first light emitter, and at least a second light emitter. The first light emitter is formed on the substrate and emits a first light having a first spectrum. The second light emitter is formed on the substrate and emits a second light having a second spectrum. The first light emitter includes a first light emitting device emitting light having a first peak wavelength and a first wavelength converter emitting first excitation light. The second light emitter includes a second light emitting device emitting the second spectrum. The first wavelength converter includes a first light transmitting layer formed of a light transmitting material and covering the first light emitting device and at least a type of wavelength conversion material. Each of the first spectrum and the second spectrum has at least one different peak wavelength. In addition, the light emitting region emits a third light having a third spectrum that is a mixture of the first spectrum and the second spectrum.

The first wavelength converter may include a first wavelength conversion material dispersed in the first light transmitting layer and emitting a green light; and a second wavelength conversion material dispersed in the first light transmitting layer and emitting a first red light.

The first wavelength converter may further include a third wavelength conversion material dispersed in the first light transmitting layer and emitting a second red light. The second red light may have a narrower full width at half maximum than the first red light.

The light emitting apparatus may further include a second light transmitting layer covering the second light emitting device or covering both the first light emitter and the second light emitting device, and a third wavelength conversion material dispersed in the second light transmitting layer. The third wavelength conversion material may emit a second red light. The second red light has a narrower full width at half maximum than the first red light.

The third spectrum may have a luminous intensity of a peak wavelength in the green wavelength band that is 40% or more of a luminous intensity of a peak wavelength in the red wavelength band.

The third spectrum may have a difference of 3% or more in luminous intensity between the peak wavelength and a valley wavelength in the green wavelength band.

The third spectrum may have a higher color rendering index than the first spectrum and the second spectrum.

In accordance with yet another aspect of the present disclosure, there is provided a light emitting apparatus including a substrate, a light emitting region including at least a first light emitter, and at least a second light emitter. The first light emitter is formed on the substrate and emits a first light having a first spectrum. The second light emitter is formed on the substrate and emits a second light having a second spectrum. Each of the first spectrum and the second spectrum may have at least one different peak wavelength. The light emitting region may emits a third light having a third spectrum that is a mixture of the first spectrum and the second spectrum.

The first spectrum may have peak wavelengths in a blue wavelength band and a red wavelength band, respectively. In addition, the second spectrum may have peak wavelengths in a blue wavelength band and a green wavelength band, respectively.

The third spectrum may have peak wavelengths in a blue wavelength band, a green wavelength band, and a red wavelength band, respectively.

The first wavelength converter may include: a first wavelength conversion material emitting light having a second peak wavelength; and a second wavelength conversion material emitting a first red light.

At least a portion of each of the first wavelength conversion material and the second wavelength conversion material may be dispersed in a different region of the first light transmitting layer.

The first wavelength converter may further include a third wavelength conversion material emitting a second red light. The second red light may have a narrower full width at half maximum than the first red light.

At least a portion of the third wavelength conversion material may be dispersed in a region different from a region in which at least one of the first light conversion material or the second light conversion material is dispersed.

The light emitting apparatus may further include a second light transmitting layer covering both the first light emitter and the second light emitting device and allowing light to transmit therethrough.

The light emitting apparatus may further include a second wavelength converter including the second light transmitting layer and a third wavelength conversion material dispersed in the second light transmitting layer and emitting a second red light. The second red light may have a narrower full width at half maximum than the first red light.

The second light emitter may further include a second light transmitting layer covering the second light emitting device and allowing light to transmit therethrough.

The second light emitter may further include a second wavelength converter including the second light transmitting layer and a third wavelength conversion material dispersed in the second light transmitting layer and emitting a second red light. The second red light may have a narrower full width at half maximum than the first red light.

A color rendering index (Ra) of the third spectrum may be higher than color rendering indexes of the first spectrum and the second spectrum.

The third spectrum may have a luminous intensity of a peak wavelength in the green wavelength band that is 40% or more of a luminous intensity of a peak wavelength in the red wavelength band.

The third spectrum may have a difference of 3% or more in luminous intensity between the peak wavelength and a valley wavelength in the green wavelength band.

The third spectrum may have a higher color rendering index than the first spectrum and the second spectrum.

In accordance with yet another aspect of the present disclosure, there is provided a light emitting apparatus including a substrate, a light emitting region including at least a first light emitter, and at least a second light emitter. The first light emitter is formed on the substrate and emits a first light having a first spectrum. The second light emitter is formed on the substrate and emits a second light having a second spectrum. Each of the first spectrum and the second spectrum has at least one different peak wavelength. The light emitting region may emit a third light having a third spectrum that is a mixture of first spectrum and the second spectrum. The second spectrum is in a region of color coordinates (0.1, 0.1), (0.3, 0.7), (0.4, 0.6), and (0.2, 0.02), and the first spectrum is in a region of color coordinates (0.3, 0.3), (0.25, 0.4), (0.5, 0.5), (0.7, 0.3), and (0.7, 0.3), and the third spectrum may be in a region of color coordinates (0.1, 0.1), (0.3, 0.7), (0.7, 0.3), and (0.2, 0.02).

The first spectrum may have peak wavelengths in a blue wavelength band and a red wavelength band, respectively. In addition, the second spectrum may have peak wavelengths in a blue wavelength band and a green wavelength band, respectively.

The third spectrum may have peak wavelengths in a blue wavelength band, a green wavelength band, and a red wavelength band, respectively.

The first wavelength converter may include: a first wavelength conversion material emitting light having a second peak wavelength; and a second wavelength conversion material emitting a first red light.

At least a portion of each of the first wavelength conversion material and the second wavelength conversion material may be dispersed in a different region of the first light transmitting layer.

The first wavelength converter may further include a third wavelength conversion material emitting a second red light. The second red light may have a narrower full width at half maximum than the first red light.

At least a portion of the third wavelength conversion material may be dispersed in a region different from a region in which at least one of the first light conversion material or the second light conversion material is dispersed.

The light emitting apparatus may further include a second light transmitting layer covering both the first light emitter and the second light emitting device and allowing light to transmit therethrough.

The light emitting apparatus may further include a second wavelength converter including the second light transmitting layer and a third wavelength conversion material dispersed in the second light transmitting layer and emitting a second red light. The second red light may have a narrower full width at half maximum than the first red light.

The second light emitter may further include a second light transmitting layer covering the second light emitting device and allowing light to transmit therethrough.

The second light emitter may further include a second wavelength converter including the second light transmitting layer and a third wavelength conversion material dispersed in the second light transmitting layer and emitting a second red light. The second red light may have a narrower full width at half maximum than the first red light.

The third spectrum may have a higher color rendering index (Ra) than the first spectrum and the second spectrum.

The third spectrum may have a luminous intensity of a peak wavelength in the green wavelength band that is 40% or more of a luminous intensity of a peak wavelength in the red wavelength band.

The third spectrum may have a difference of 3% or more in luminous intensity between the peak wavelength and a valley wavelength in the green wavelength band.

The color rendering index of the third spectrum may be higher than the color rendering indexes of the first spectrum and the second spectrum.

In accordance with yet another aspect of the present disclosure, there is provided a light emitting apparatus including a substrate, a light emitting region including a first light emitter, and a second light emitter. The first light emitter is formed on the substrate and emits a first light having a first spectrum. The second light emitter is formed on the substrate and emits a second light having a second spectrum. Each of the first spectrum and the second spectrum has at least one different peak wavelength. The light emitting region may emit a third light having a third spectrum that is a mixture of first spectrum and the second spectrum. The third spectrum may have a variable color rendering index (Ra) depending on an operation ratio of the first light emitter and the second light emitter.

The first spectrum may have peak wavelengths in a blue wavelength band and a red wavelength band, respectively. In addition, the second spectrum may have peak wavelengths in a blue wavelength band and a green wavelength band, respectively.

The third spectrum may have peak wavelengths in a blue wavelength band, a green wavelength band, and a red wavelength band, respectively.

The third spectrum may have a luminous intensity of a peak wavelength in the green wavelength band that is 40% or more of a luminous intensity of a peak wavelength in the red wavelength band.

The third spectrum may have a difference of 3% or more in luminous intensity between the peak wavelength and a valley wavelength in the green wavelength band.

The color rendering index of the third spectrum may be higher than the color rendering indexes of the first spectrum and the second spectrum.

The first spectrum may have peak wavelengths in a blue wavelength band and a red wavelength band, respectively. In addition, the second spectrum may have peak wavelengths in a blue wavelength band and a green wavelength band, respectively.

The third spectrum may have peak wavelengths in a blue wavelength band, a green wavelength band, and a red wavelength band, respectively.

The first wavelength converter may include: a first wavelength conversion material emitting light having a second peak wavelength; and a second wavelength conversion material emitting a first red light.

At least a portion of each of the first wavelength conversion material and the second wavelength conversion material may be dispersed in a different region of the first light transmitting layer.

The first wavelength converter may further include a third wavelength conversion material emitting a second red light. The second red light may have a narrower full width at half maximum than the first red light.

At least a portion of the third wavelength conversion material may be dispersed in a region different from a region in which at least one of the first light conversion material or the second light conversion material is dispersed.

The light emitting apparatus may further include a second light transmitting layer covering both the first light emitter and the second light emitting device and allowing light to transmit therethrough.

The light emitting apparatus may further include a second wavelength converter including the second light transmitting layer and a third wavelength conversion material dispersed in the second light transmitting layer and emitting a second red light. The second red light may have a narrower full width at half maximum than the first red light.

The second light emitter may further include a second light transmitting layer covering the second light emitting device and allowing light to transmit therethrough.

The second light emitter may further include a second wavelength converter including the second light transmitting layer and a third wavelength conversion material dispersed in the second light transmitting layer and emitting a second red light. The second red light may have a narrower full width at half maximum than the first red light.

The third spectrum may have a higher color rendering index (Ra) than the first spectrum and the second spectrum.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the inventive concepts.

FIG. 1 is a view of a light emitting apparatus according to a first embodiment of the present disclosure.

FIG. 2 is a graph depicting a light emission spectrum of a first light emitter of the light emitting apparatus according to the first embodiment of the present disclosure.

FIG. 3 is a graph depicting a light emission spectrum of a second light emitter of the light emitting apparatus according to the first embodiment of the present disclosure.

FIG. 4 is a graph depicting a light emission spectrum of the light emitting apparatus according to the first embodiment of the present disclosure.

FIG. 5 is a graph depicting light emission spectra of the light emitting apparatus according to the first embodiment depending on a ratio of a green wavelength band of the second light emitter.

FIG. 6 is a graph depicting the color rendering index (CRI) of the light emitting apparatus according to the first embodiment depending on the ratio of the green wavelength band of the second light emitter.

FIG. 7 is a view of a light emitting apparatus according to a second embodiment of the present disclosure.

FIG. 8 is a graph depicting a light emission spectrum of a first light emitter of the light emitting apparatus according to the second embodiment of the present disclosure.

FIG. 9 is a graph depicting light emission spectra of the light emitting apparatus according to the second embodiment of the present disclosure depending upon the ratio of the third wavelength conversion material of the first light emitter.

FIG. 10 is a graph depicting the color rendering index (CRI) of the light emitting apparatus according to the second embodiment depending upon a ratio of a green wavelength band of the second light emitter and a ratio of a second red light of the first light emitter.

FIG. 11 is a view of a light emitting apparatus according to a third embodiment of the present disclosure.

FIG. 12 is a view of a light emitting apparatus according to a fourth embodiment of the present disclosure.

FIG. 13 is a view of a light emitting apparatus according to a fifth embodiment of the present disclosure.

FIG. 14 is a view of a light emitting apparatus according to a sixth embodiment of the present disclosure.

FIG. 15 is a view of a light emitting apparatus according to a seventh embodiment of the present disclosure.

FIG. 16 is a view of a lighting apparatus including a light emitting apparatus according to an embodiment of the present disclosure.

FIG. 17 is a view of a display apparatus including a light emitting apparatus according to an embodiment of the present disclosure.

### DETAILED DESCRIPTION

In the following description, for the purposes of explanation, numerous specific details are set forth in order to provide thorough understanding of various exemplary embodiments or implementations of the present disclosure. As used herein, “embodiments” and “implementations” are interchangeable terms for non-limiting examples of devices or methods employing one or more of the inventive concepts disclosed herein. It will be apparent, however, that various exemplary embodiments may be practiced without these specific details or with one or more equivalent arrangements. In other instances, well-known structures and devices are shown in block diagram form in order to avoid unnecessarily obscuring various exemplary embodiments. Further, various exemplary embodiments may be different, but do not have to be exclusive. For example, specific shapes, configurations, and characteristics of an exemplary embodiment may be used or implemented in another exemplary embodiment without departing from the inventive concepts.

Unless otherwise specified, the illustrated exemplary embodiments are to be understood as providing exemplary features of varying detail of some ways in which the inventive concepts may be implemented in practice. Therefore, unless otherwise specified, the features, components, modules, layers, films, panels, regions, and/or aspects (hereinafter individually or collectively referred to as “elements”) of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, and property of the elements, unless specified. Further, in the accompanying drawings, the size and relative sizes of elements may be exaggerated for clarity and/or descriptive purposes. When an exemplary embodiment is implemented differently, a specific process order may be performed differently from the described order. For example, two consecutively described processes may be performed substantially at the same time or performed in an order opposite the described order. In addition, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the DR1-axis, the DR2-axis, and the DR3-axis are not limited to three axes of a rectangular coordinate system, such as the x, y, and z-axes, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (for example, as in “sidewall”), and the like, may be used herein for descriptive purposes, and, thereby, to describe one element's relationship to other element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (for example, rotated 90 degrees or at other orientations), and, as such, the spatially relative descriptors used herein may likewise interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various exemplary embodiments are described herein with reference to sectional and/or exploded illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some exemplary embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (for example, microcode) to perform various functions discussed herein and may optionally be driven by firmware and/or software. It is also contemplated that each block, unit, and/or module may be implemented by dedicated hardware, or as a combination of dedicated hardware to perform some functions and a processor (for example, one or more programmed microprocessors and associated circuitry) to perform other functions. Also, each block, unit, and/or module of some exemplary embodiments may be physically separated into two or more interacting and discrete blocks, units, and/or modules without departing from the scope of the inventive concepts. Further, the blocks, units, and/or modules of some exemplary embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure pertains. Terms, such as those defined in commonly used dictionaries, should be interpreted as having a meaning that is consistent with their meaning in the context of the relevant art and should not be interpreted in an idealized or overly formal sense, unless expressly so defined herein.

Hereinafter, light emitting apparatuses according to the present disclosure will be described in detail with reference to the drawings.

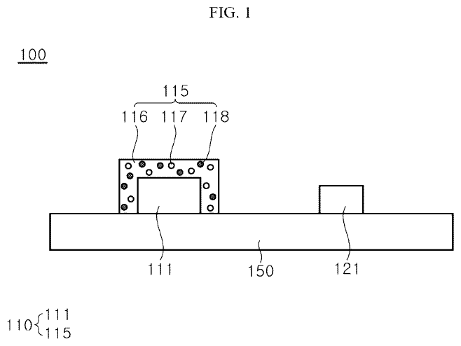

FIG. 1 is a view of a light emitting apparatus according to a first embodiment of the present disclosure.

Referring to FIG. 1, the light emitting apparatus 100 according to the first embodiment may include a substrate 150, a first light emitter 110, and a second light emitter.

According to embodiments of the present disclosure, the substrate 150 may include wiring electrically connected to the first light emitter 110 and the second light emitter. For example, the substrate 150 may be a printed circuit board. However, the substrate 150 is not limited thereto and may be any type of substrate that can control operation of the light emitting apparatus 100.

The first light emitter 110 and the second light emitter may emit light when supplied with drive power through the wiring of the substrate 150 to which the first light emitter 110 and the second light emitter are electrically connected. Here, the wiring of the substrate 150 may be a drive circuit for controlling operation of the first light emitter 110 and the second light emitter. In addition, the substrate 150 may include a drive device for controlling operation of the first light emitter 110 and the second light emitter instead of the drive circuit, or may include both the drive circuit and the drive device.

In addition, the ratio of light emitted from the first light emitter 110 to light emitted from the second light emitter may be adjusted by adjusting the drive power supplied to each of the first light emitter 110 and the second light emitter through the substrate 150.

Thus, the light emitting apparatus 100 can easily adjust the color coordinates and CRI of light emitted therefrom and may emit light of a predetermined color.

The first light emitter 110 emits a white light including a first spectrum and may include a first light emitting device 111 and a first wavelength converter 115.

According to the embodiment, the first light emitting device 111 may include a light emitting diode chip that emits a blue light.

The first wavelength converter 115 may be formed on the substrate 150 to cover the first light emitting device 111. For example, the first wavelength converter 115 may cover upper and side surfaces of the first light emitting device 111. That is, the first wavelength converter 115 may cover a light emitting surface through which light emitted from the first light emitting device 111 is emitted.

The first wavelength converter 115 may convert the wavelength of a fraction of light emitted from the first light emitting device to emit light of a different color. The first wavelength converter 115 may include a first light transmitting layer 116, a first wavelength conversion material 117, and a second wavelength conversion material 118.

The first wavelength conversion material 117 may emit light having a peak wavelength in the green or yellow wavelength band. For example, the first wavelength conversion material 117 may include at least one of LuAG series, YAG series, beta-SiAlON series, nitride series, silicate series, halophosphide series, or oxynitride series.

The second wavelength conversion material 118 may emit light having a peak wavelength in the red wavelength band. For example, the second wavelength conversion material 118 may include at least one of nitride series, such as CASN, CASON, and SCASN, silicate series, sulfide series, or fluoride series.

However, it should be understood that the first wavelength conversion material 117 and the second wavelength conversion material 118 are not limited thereto. The first wavelength conversion material 117 and the second wavelength conversion material 118 may be selected from any materials capable of emitting wavelength-converted light through conversion of the wavelength of absorbed light, such as phosphors, quantum dots (QDs), or organic dyes.

The first light transmitting layer 116 may allow light emitted from the first light emitting device 111 to transmit therethrough. For example, the first light transmitting layer 116 may be formed of a transparent resin, such as an epoxy resin, a silicone resin, a fluorinated resin, or the like. Alternatively, the first light transmitting layer 116 may be formed of a light transmitting material, such as glass or ceramic. Alternatively, the first light transmitting layer 116 may be formed of a permeable material, such as fused silica, borosilicate, soda-lime glass, aluminosilicate, fluoro resins, or the like. Here, the first light transmitting layer 116 may include a material capable of minimizing the absorption rate of light emitted from the first light emitting device 111 to increase luminous efficacy, in which the absorption rate of light emitted from the first light emitting device 111 may be less than 10%. For example, the first light transmitting layer may have an absorption rate of less than 10% with respect to light emitted from the first light emitting device 111 in the blue wavelength band.

The first wavelength conversion material 117 and the second wavelength conversion material 118 are dispersed in the first light transmitting layer 116.

The first wavelength conversion material 117 and the second wavelength conversion material 118 may be excited by the blue light emitted from the first light emitting device 111 to emit different colors of light, respectively. For example, each of the first wavelength conversion material 117 and the second wavelength conversion material 118 may include at least one of quantum dots or phosphors that emit light of a different color than the blue light emitted from the first light emitting device 111.

For example, the first wavelength conversion material 117 may be excited by the blue light emitted from the first light emitting device 111 to emit a green light. Further, the second wavelength conversion material 118 may be excited by the blue light emitted from the first light emitting device 111 to emit a red light.

Thus, the first light emitter 110 according to the embodiment may emit the first white light including the first spectrum that is a mixture of the blue light emitted from the first light emitting device 111, the green light emitted from the first wavelength conversion material 117, and/or the red light emitted from the second wavelength conversion material 118.

Referring to FIG. 1, the first wavelength conversion material 117 and the second wavelength conversion material 118 are evenly dispersed throughout the first light transmitting layer 116. However, a distribution form in which the first wavelength conversion material 117 and the second wavelength conversion material 118 are dispersed in the first light transmitting layer 116 is not limited to a distribution form shown in FIG. 1. The first wavelength conversion material 117 and the second wavelength conversion material 118 may be partially or entirely dispersed in different regions of the first light transmitting layer 116. For example, the first wavelength conversion material 117 may be dispersed in an upper region of the first light transmitting layer 116 and the second wavelength conversion material 118 may be dispersed in a lower region of the first light transmitting layer 117. In addition, both the first wavelength conversion material 117 and the second wavelength conversion material 118 may be deposited in the lower region of the first light transmitting layer 116. Here, the first wavelength conversion material 117 may be disposed above the second wavelength conversion material 118 and the second wavelength conversion material 118 may be disposed closer to the first light emitting device 111 than the first wavelength conversion material 117. The second wavelength conversion material 118, which converts light of a relatively long wavelength, may be disposed close to the light emitting device, thereby improving light conversion efficiency through reduction of reabsorption of short wavelengths. Conversely, the first wavelength conversion material 117 may be disposed below the second wavelength conversion material 118, the first wavelength conversion material 117 may be disposed closer to the first light emitting device 111 than the second wavelength conversion material 118, and a fraction of light converted by the first wavelength conversion material 117 may be converted again in the second wavelength conversion material 118, thereby enabling reduction in manufacturing costs through reduction in amount of the second wavelength conversion material 118 to be used. Furthermore, conversion of the phosphors may also be achieved by disposing at least one of the first wavelength conversion material 117 or the second wavelength conversion material 118 only in one region of the first light emitting device 111, thereby enabling reduction in manufacturing costs through reduction in amount of the wavelength conversion material. As such, the distribution form of the first wavelength conversion material 177 and the second wavelength conversion material 118 may be varied, as needed.

The second light emitter may include a second light emitting device 121.

According to this embodiment, the second light emitting device 121 may be a light emitting diode that emits a white light including a second spectrum.

For example, the second light emitting device 121 may be formed on the substrate 150 through control of dopants and doping according to regions to simultaneously emit a blue light, a green light, and a red light from each region. Here, the second light emitting device 121 may emit a second white light including the second spectrum, which is a mixture of the blue light, the green light, and the red light emitted from each region.

The second white light emitted from the second light emitting device 121 may be light having color coordinates in a white range on the CIE color coordinate system. Alternatively, the second white light of the second light emitting device 121 may be light having color coordinates close to the white range, such as bluish white light or greenish white light, even though the second white light is not included in the white range. Further, the second white light of the second light emitting device 121 may have two or more peak wavelengths. Furthermore, the second white light including the second spectrum may have a color temperature of 7,000 K or higher and may have a high color temperature similar to a blue light that may not be measured by spectrometer.

Alternatively, the second light emitting device 121 may be formed by forming a light emitting diode emitting a blue light, a light emitting diode emitting a green light, and a light emitting diode emitting a red light, respectively, followed by arranging the light emitting diodes in a horizontal direction or by stacking the light emitting diodes in a vertical direction.

That is, in this embodiment, the second light emitter has a structure in which the second light emitting device 121 emits a white light without any wavelength conversion material, and may be realized by the second light emitting device 121 per se.

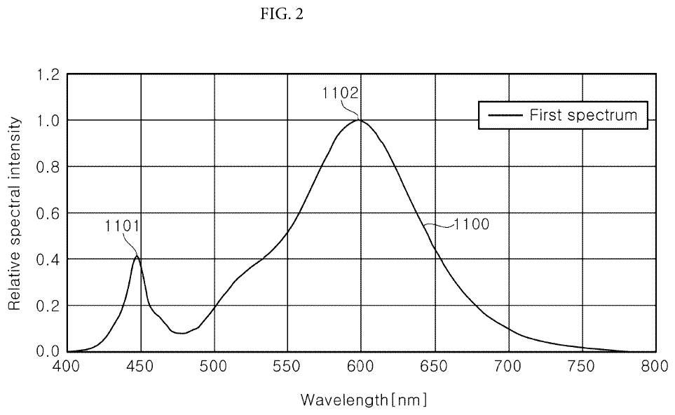

The second light emitting device 121 according to this embodiment may emit a white light including the second spectrum obtained by mixing at least two of a blue light, a green light, or a red light. A light spectrum of the second light emitting device 121 according to this embodiment may have peak wavelengths in at least two wavelength bands among a blue wavelength band, a green wavelength band, and a red wavelength band, as shown in FIG. 2. Here, relative values of two peak wavelengths may be the same or different. For example, the blue light may have a peak wavelength in the wavelength band of about 400 nm to about 500 nm, the green light may have a peak wavelength in the wavelength band of about 500 nm to about 570 nm, and the red light may have a peak wavelength in the wavelength band of about 590 nm to about 780 nm. It can be understood that the blue light according to the embodiment includes not only a blue light but also light in a wavelength band adjacent to the blue wavelength band. That is, the blue light according to this embodiment includes light having a peak wavelength in a wavelength range including an indigo wavelength band of about 400 nm to about 450 nm and a blue wavelength band of about 450 nm to about 500 nm. Furthermore, it can be understood that the red light according to this embodiment includes not only a red light but also light in a wavelength band adjacent to the red wavelength band. That is, the red light according to this embodiment includes light having a peak wavelength in a wavelength range including an orange wavelength band of about 590 nm to about 610 nm and a red wavelength band of about 610 nm to about 780 nm. Further, the second light emitting device 121 may have a normalized intensity or relative intensity of 1 at about 455 nm and a normalized intensity or relative intensity of 1 to 0.2 in the wavelength band of about 490 nm to 570 nm. However, it should be understood that the present disclosure is not limited thereto.

According to the embodiment, both the first light emitter 110 and the second light emitter may emit a white light. However, the first white light including the first spectrum of the first light emitter 110 and the second white light including the second spectrum of the second light emitter have has different color temperatures. For example, the first white light of the first light emitter 110 may have a lower color temperature than the second white light of the second light emitter. For example, the first light emitter 110 may have a color temperature of 6,000 K or less and the second light emitter may have a color temperature of 6,000 K or more. For example, the first light emitter 110 and the second light emitter may have a color temperature difference of 3,000 K or more.

In addition, the first white light including the first spectrum of the first light emitter 110 and the second white light including the second spectrum of the second light emitter may have different color coordinates. For example, the color coordinates of the second white light may be placed within a region of (0.1, 0.1), (0.3, 0.7), (0.4, 0.6), and (0.2, 0.02). Further, the color coordinates of the first white light may be placed within a region of (0.3, 0.3), (0.25, 0.4), (0.5, 0.5), and (0.7, 0.3). The color coordinates of a third white light, which is a mixture of the first white light and the second white light, may be placed within a region of (0.1, 0.1), (0.3, 0.7), (0.7, 0.3), and (0.2, 0.02). However, it should be understood that these color coordinates of the first white light and the second white light are provided by way of example and other implementations are possible.

Thus, the light emitting apparatus 100 according to the first embodiment emits the third white light including the third spectrum, which is a mixture of the first white light of the first light emitter 110 and the second white light of the second light emitter having different emission spectra.

Further, the first light emitter 110 and the second light emitter may have different dominant wavelengths. For example, the second light emitter may have a dominant wavelength in the wavelength band of about 460 nm to about 500 nm and the first light emitter may have a dominant wavelength in the wavelength band of about 490 nm to about 600 nm. Here, the dominant wavelength represents the wavelength of a color perceived by three stimuli corresponding to the human visual sensitivity curve of the spectrum emitted by a light source and can be measured by a spectrometer or spectroscope. That is, the dominant wavelength may be a single wavelength perceived by the human eye among multiple wavelengths of light emitted from the light source. In addition, the first light emitter 110 may emit light including the first spectrum, the first spectrum may include at least a first peak, and the first peak may be a peak wavelength in the blue wavelength band. Further, the second light emitting device 121 included in the second light emitter may emit light including the second spectrum, the second spectrum may include at least a second peak, and the second peak may be a peak wavelength in the green wavelength band.

The first spectrum of the first white light of the first light emitter 110, the second spectrum of the second white light of the second light emitter, and the third spectrum of the third white light of the light emitting apparatus according to the first embodiment will be described with reference to FIG. 2 to FIG. 6.

FIG. 2 to FIG. 6 are graphs illustrating the effects of the light emitting apparatus according to the first embodiment of the present disclosure.

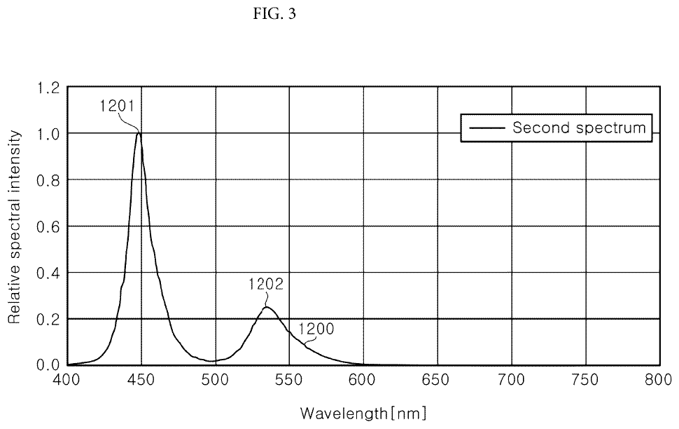

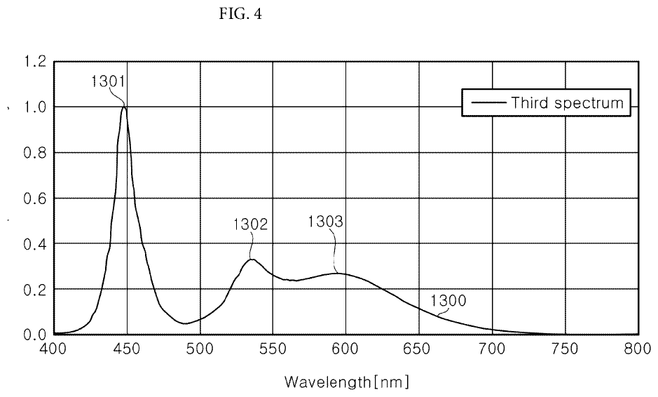

FIG. 2 is a graph depicting a light emission spectrum of the first light emitter 110 of the light emitting apparatus 100 according to the first embodiment of the present disclosure. FIG. 3 is a graph depicting a light emission spectrum of the second light emitter 110 of the light emitting apparatus 100 according to the first embodiment of the present disclosure. FIG. 4 is a graph depicting a light emission spectrum of the light emitting apparatus 100 according to the first embodiment of the present disclosure.

Referring to FIG. 2, the first light emitter 110 emits a first white light of a first spectrum 1100 having peak wavelengths in the blue wavelength band and the red wavelength band, respectively. In the first spectrum 1100, a peak wavelength in the blue wavelength band is a first-1 peak wavelength 1101, and a peak wavelength in the red wavelength band is a first-2 peak wavelength 1102. Although not shown in FIG. 2, the first spectrum 1100 of the first light emitter 110 may also have a peak wavelength in the green wavelength band or the yellow wavelength band. Here, a difference in intensity between the peak wavelength in the red wavelength band and the peak wavelength in the green wavelength band or the yellow wavelength band may be small, for example, from about 10% to about 40%. Further, when the first spectrum 1100 has a peak wavelength in the green wavelength band or the yellow wavelength band, the peak wavelength may have a lower intensity than the peak wavelength in the red wavelength band or the peak wavelength in the blue wavelength band.

Referring to FIG. 3, the second light emitter emits a second white light of a second spectrum 1200 including peak wavelengths in the blue wavelength band and the green wavelength band, respectively. In the second spectrum 1200, a peak wavelength in the blue wavelength band is a second-1 peak wavelength 1201, and a peak wavelength in the green wavelength band is a second-2 peak wavelength 1202.

Both the first spectrum 1100 and the second spectrum 1200 have the peak wavelengths in the blue wavelength band.

Further, in the second spectrum 1200, the second-1 peak wavelength 1201 in the blue wavelength band may have a normalized intensity or relative intensity of 1 and the second-2 peak wavelength 1202 in the green wavelength band may have a normalized intensity or relative intensity of 1 to 0.2. Referring to FIG. 3, in the second spectrum 1200, the second-1 peak wavelength 1201 has a normalized intensity or relative intensity of 1 and the second-2 peak wavelength 1202 has a normalized intensity or relative intensity of about 0.25.

Referring to FIG. 2 and FIG. 3, comparing the first spectrum 1100 with the second spectrum 1200, the second spectrum 1200 differs from the first spectrum 1100 in that the second spectrum 1200 has a second-2 peak wavelength 1202 in the wavelength band of about 495 nm to about 580 nm. In addition, the second spectrum 1200 may have a second-2 peak wavelength 1202 in the green wavelength band. Further, the second spectrum 1200 differs from the first spectrum 1100 in that the second spectrum 1200 does not have a peak wavelength in the red wavelength band.

Conversely, unlike the second spectrum 1200, the first spectrum 1100 may have the first-2 peak wavelength 1102 in the red wavelength band and may not have a peak wavelength in the green wavelength band. Alternatively, the first spectrum 1100 may have a peak wavelength in the green wavelength band, which has lower luminous intensity than a peak wavelength in the red wavelength band. Here, the luminous intensity of the peak wavelength in the green wavelength band may be less than 40% of the luminous intensity of the peak wavelength in the red wavelength band.

Here, the blue wavelength band ranges from about 400 nm to about 500 nm, the green wavelength range ranges from about 500 nm to about 570 nm, and the red wavelength range ranges from about 590 nm to about 780 nm.

The light emitting apparatus 100 according to the first embodiment may emit a third white light including a third spectrum 1300 shown in FIG. 4, as a mixture of the first white light including the first spectrum 1100 of FIG. 2 with the second white light including the second spectrum 1200 of FIG. 3.

Referring to FIG. 4, the light emitting apparatus 100 according to the first embodiment may emit the third white light of the third spectrum 1300 that has peak wavelengths in the blue wavelength band, the green wavelength band, and the red wavelength band, respectively. In the third spectrum 1300, a peak wavelength in the blue wavelength band is a third-1 peak wavelength 1301, a peak wavelength in the green wavelength band is a third-2 peak wavelength 1302, and a peak wavelength in the red wavelength band is a third-2 peak wavelength 1303. Referring to FIG. 2 to FIG. 4, it can be seen that the third-1 peak wavelength 1301 can be affected by the first-1 peak wavelength 1101 of the first spectrum 1100 and the second-1 peak wavelength 1201 of the second spectrum 1200, the third-2 peak wavelength 1302 can be affected by the second-2 peak wavelength 1202 of the second spectrum 1200, and the third-3 peak wavelength 1303 can be affected by the first-2 peak wavelength 1102 of the first spectrum 1100.

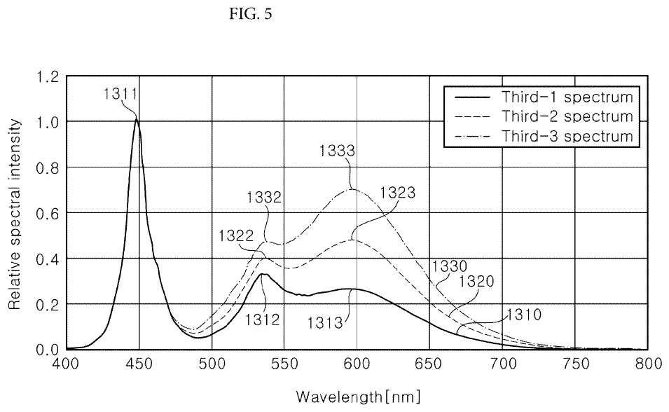

FIG. 5 is a graph depicting a light emission spectrum of the light emitting apparatus 100 according to the first embodiment depending upon the ratio of the green wavelength band of the second light emitter.

More specifically, FIG. 5 illustrates a change in spectrum of the third spectrum 1300 when the ratio of a green light to a red light is changed by adjusting the emission ratio of the second light emitter and the first light emitter.

Referring to FIG. 5, the light emitting apparatus 100 emits light of a third-1 spectrum 1310, light of a third-2 spectrum 1320, and light of a third-3 spectrum 1330 in order of increasing ratio of the blue wavelength band to the green wavelength band.

A peak wavelength in the green wavelength band of the third-1 spectrum 1310 is a third-21 peak wavelength 1312, a peak wavelength in the green wavelength band of the third-2 spectrum 1320 is a third-22 peak wavelength 1322, and a peak wavelength in the green wavelength band of the third-3 spectrum 1330 is a third-23 peak wavelength 1332.

Referring to FIG. 5, the third-23 peak wavelength 1332 of the third-3 spectrum 1330 is greater than the third-22 peak wavelength 1322 of the third-2 spectrum 1320, and the third-21 peak wavelength 1312 of the third-1 spectrum 1310 is less than the third-22 peak wavelength 1322 of the third-2 spectrum 1320.

In other words, it can be seen that, as the intensity (luminous intensity) of the peak wavelength of the green wavelength band of the third spectrum 1300 increases, the area of the green wavelength band of the third spectrum 1300 increases, thereby increasing the intensity or quantity of the green light in the third spectrum 1300.

Like the third-2 spectrum 1320 and the third-3 spectrum 1330, the third spectrum 1300 may have lower luminous intensity of the peak wavelength in the green wavelength band than the luminous intensity of the peak wavelength in the red wavelength band. For example, the luminous intensity of the peak wavelength in the green wavelength band may be 40% or more, specifically 50% or more, of the luminous intensity of the peak wavelength in the red wavelength band. Alternatively, like the third-1 spectrum 1310, the third spectrum 1300 may have higher luminous intensity of the peak wavelength in the green wavelength band than the luminous intensity of the peak wavelength in the red wavelength band. For example, the luminous intensity of the peak wavelength in the green wavelength band may be 110% or more of the luminous intensity of the peak wavelength in the red wavelength band.

In addition, the third spectrum 1300 may have higher luminous intensity of the peak wavelength in the blue wavelength band than the luminous intensity of the peak wavelength in the red wavelength band.

Further, the third spectrum 1300 may have a difference of 3% or more in luminous intensity between the peak wavelength and a valley wavelength in the green wavelength band. Here, the valley wavelength in the green wavelength band refers to a wavelength having the lowest luminous intensity in the green wavelength band. As a result, the second light emitter according to this embodiment may emit light having an improved color reproduction rate, thereby improving the color reproduction rate of the second white light.

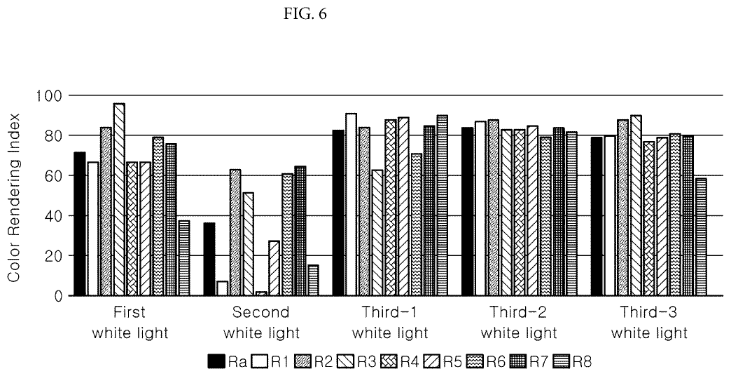

FIG. 6 is a graph depicting the color rendering index (CRI) of the light emitting apparatus 100 according to the first embodiment depending on the ratio of the green wavelength band of the second light emitter.

The color rendering index refers to a numerical representation of the degree of color reproduction of an illuminated object and corresponds to the degree of similarity between a color of an object illuminated by a light source and a color of the object illuminated by sunlight.

Referring to FIG. 6, the first spectrum of the first light emitter 110 has a color rendering index Ra of 71. For the first white light, R1, R4, R5, and R8 are significantly different from R2, R3, R6, and R7, respectively. Among R1 to R8 of the first white light, R3 has the maximum value of 95 and R8 has the minimum value of 37. That is, the first white light has a minimum value that is less than 50% of the maximum value among R1 to R8.

However, the third-1 spectrum, the third-2 spectrum, and the third-3 spectrum, have a smaller difference between R1 and R8 than the first spectrum.

Each of a difference between the maximum value of R1 and the minimum value of R3 for the third-1 spectrum, a difference between the maximum value of R2 and the minimum value of R6 for the third-2 spectrum, and a difference between the maximum value of R3 and the minimum value of R8 for the third-3 spectrum is less than 50%. That is, among R1 to R8 of the third-1 spectrum, the third-2 spectrum, and the third-3 spectrum, the minimum value is 50% or more of the maximum value.

In addition, the third-1 spectrum has an Ra of 82, the third-2 spectrum has an Ra of 83, and the third-3 spectrum has an Ra of 78, all of which have a higher color rendering index than the first white light.

Thus, it can be seen that mixture of light of the first spectrum with light of the second spectrum reduces the difference between the maximum value R1 and the minimum value R8, thereby increasing the color rendering index Ra, which is an average value.

It can also been seen that, when light of the first spectrum having no or a low peak wavelength in the green wavelength band is mixed with light of the second spectrum having a peak wavelength in the green wavelength band, a third spectrum having a peak wavelength in each of the blue wavelength band, the green wavelength band, and the red wavelength band is generated. That is, according to the embodiment, color rendering properties can be improved by adding light of the second spectrum having a peak wavelength in the green wavelength band to light of the first spectrum having no or a low peak wavelength in the green wavelength band to supplement a green light. Here, the color rendering indexes R3 to R5 may be 60 or more and a difference between the color rendering indexes may be less than 30.

A typical light emitting apparatus includes a light emitting diode chip emitting a blue light and a phosphor layer covering the light emitting diode chip. However, the typical light emitting apparatus is not highly color rendering, like the first light emitter 110 according to the present disclosure.

Thus, the light emitting apparatus 100 according to this embodiment includes both the first light emitter 110 and the second light emitter emitting a white light having different emission spectra, thereby improving the color rendering properties, as compared with a typical light emitting apparatus including only the first light emitter 110. Here, the light emitting apparatus 100 may have a higher color rendering properties than the first light emitter 110 or the second light emitter 120.

In addition, in order to improve the color rendering properties of typical light emitting apparatuses, it is necessary to increase the content of phosphors in the phosphor layer. However, since the phosphors are expensive, the manufacturing cost of the light emitting apparatus increases rapidly with increasing content of the phosphors. Further, since the phosphors are degraded by heat from the light emitting diode chip, the quantity of degraded phosphors increases with increasing content of the phosphors. Accordingly, as the content of the phosphors increases, light emitting efficiency and reliability of the light emitting apparatus decreases.

Such a typical light emitting apparatus does not realize a white light with a desired color temperature or color rendering index due to various problems including degradation and the like, which can cause the ratio of a blue light, a red light, and a green light to deviate from a predetermined ratio.

The light emitting apparatus 100 according to the embodiment can improve the color rendering properties by adding the second light emitting device 121, which emits a white light with a different emission spectrum than the first light emitter 110, to the first light emitter 110 formed in a typical manner. More specifically, the light emission spectrum of the second light emitting device 121 may serve to supplement a low luminous intensity region of the light emission spectrum of the first light emitter 110. Thus, the light emitting apparatus 100 according to the embodiment may emit a white light having high color rendering properties by including the first light emitter 110 and the second light emitting device that supplements the luminous intensity of a deficient color gamut of the first light emitter 110. Further, the light emitting apparatus 100 according to this embodiment can prevent deterioration in reliability and luminous efficacy that occurs upon increase in content of the phosphors to improve the color rendering properties.

In addition, the light emitting apparatus 100 according to this embodiment can reduce costs for implementing high color rendering properties by minimizing the use of costly wavelength conversion materials, such as phosphors containing rare-earth elements, for example, Lu, Sc, Y, Eu, Ce, Sb, Tb, La, and the like.

Further, since the light emitting apparatus 100 according to this embodiment includes the second light emitting device 121 in addition to the first light emitter 110, the light emitting apparatus 100 has a simpler structure and a smaller size than a typical light emitting apparatus that requires a light emitting diode chip and a phosphor layer for each color of light, and can reduce the manufacturing process and costs.

Although not shown in FIG. 1, the light emitting apparatus 100 may further include a protective layer formed on the substrate 150 and covering at least one of the first light emitter 110 or the second light emitting device 121, as needed. The protective layer may serve to protect the first light emitter 110 and the second light emitting device 121 from an external environment and may also serve to adjust the beam angle of light emitted from the light emitting apparatus 100, like a lens. The protective layer may be formed of a material through which light emitted from the first light emitter 110 and the second light emitting device 121 is transmitted. For example, the protective layer may be formed of a transparent resin, such as an epoxy resin, a silicone resin, a fluorinated resin, or the like. Alternatively, the protective layer may be formed of a light transmitting material, such as glass or ceramic. Alternatively, the protective layer may be formed of a permeable material, such as fused silica, borosilicate, soda-lime glass, aluminosilicate, fluoro resins, or the like. When the protective layer is formed of the above material, the protective layer may be formed of the same material as or a different material than the light transmitting layer. Light emitting apparatuses according to following embodiments may also further include a protective layer covering at least one of the first light emitter or the second light emitter, as needed. In the following description of embodiments, description of the same configuration as the earlier embodiments will be omitted or briefly described. Accordingly, for detailed description of the same configuration, refer to previous description of the same configuration.

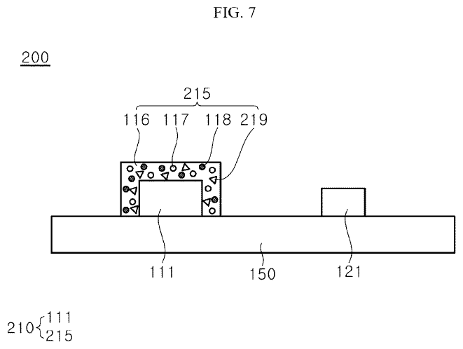

FIG. 7 is a view of a light emitting apparatus according to a second embodiment of the present disclosure.

Referring to FIG. 7, the light emitting apparatus 200 according to the second embodiment may include a substrate 150, a first light emitter 210, and a second light emitter 121.

The substrate 150 and the second light emitter 121 of the light emitting apparatus 200 according to the second embodiment are the same as the substrate 150 and the second light emitter 121 of the light emitting apparatus 100 (see FIG. 1) according to the first embodiment.

The first light emitter 210 according to this embodiment includes a first light emitting device 111 and a first wavelength converter 215.

Here, the first light emitting device 111 is the same as the first light emitting device 111 of the light emitting apparatus (100 of FIG. 1) according to the first embodiment.

The first wavelength converter 215 may include a first light transmitting layer 116, a first wavelength conversion material 117, a second wavelength conversion material 118, and a third wavelength conversion material 219. The first to third wavelength conversion materials 117, 118, 219 may be excited by light emitted from the first light emitting device 111 to emit light of a different color than light emitted from the first light emitting device 111. For example, each of the first to third wavelength conversion materials 117, 118, 219 may include at least one of quantum dots or phosphors that emit light of a different color than the blue light of the first light emitting device 111.

For example, the first wavelength conversion material 117 may be excited by the blue light of the first light emitting device 111 to emit a green light. The second wavelength conversion material 118 may be excited by the blue light of the first light emitting device 111 to emit a first red light.

In addition, the third wavelength conversion material 219 may be excited by the blue light of the first light emitting device 111 to emit a second red light. Here, the third wavelength conversion material 219 may emit the second red light having a narrower full width at half maximum than the first red light of the second wavelength conversion material 118. By way of example, the first red light may have a full width at half maximum of about 80 nm to about 110 nm and the second red light may have a half width at half maximum of about 10 nm to about 100 nm.

Further, light emitted from the third wavelength conversion material 219 upon excitation thereof may have one different peak wavelength from light emitted from the second wavelength conversion material 118.

Furthermore, the third wavelength conversion material 219 may be excited by absorbing light emitted from the first light emitting device 111 without absorbing light emitted from the first wavelength conversion material 117 and light emitted from the second wavelength conversion material 118. Thus, even when the third wavelength conversion material 219 is added, the quantity of the green light emitted from the first wavelength conversion material 117 and the quantity of the first red light emitted from the second wavelength conversion material 118 of the first light emitter 210 can be reduced or the variation of the ratio of the green light and the first red light can be minimized.

The third wavelength conversion material 219 may include a material emitting light having a full width at half maximum of about 50 nm or less. In addition, the third wavelength conversion material 219 may include red phosphors or quantum dots having a full width at half maximum of about 40 nm or less. For example, the red phosphors may include fluoride-based phosphors. Further, the red phosphor may include A₂MF₆:Mn⁴⁺, where A may be Li, Na, K, Ba, Rb, Cs, Mg, Ca, Se, or Zn, and M may be Ti, Si, Zr, Sn, or Ge. Further, the quantum dots may include CdTe or CdSe.

Referring to FIG. 7, the first to third wavelength conversion materials 117, 118, 219 are evenly dispersed throughout the first light transmitting layer 116. However, the structure in which the first to third wavelength conversion materials 117, 118, 219 are dispersed in the first light transmitting layer 116 is not limited to the structure shown in FIG. 7. Some or the entirety of each of the first to third wavelength conversion materials 117, 118, 219 may be dispersed in different regions of the first light transmitting layer 116. For example, the first wavelength conversion material 117 or the second wavelength conversion material 118 may be dispersed in an upper region of the first light transmitting layer 116 and the third wavelength conversion material 219 may be dispersed in a lower region of the first light transmitting layer 117. Alternatively, for example, the first wavelength conversion material 117 may be dispersed in an upper region of the first light transmitting layer 116, the second wavelength conversion material 118 may be dispersed in a central region of the first light transmitting layer 116, and the third wavelength conversion material 219 may be dispersed in a lower region of the first light transmitting layer 117. In addition, all of the first to third wavelength conversion materials 117, 118, 219 may be deposited in the lower region of the first light transmitting layer 116. Here, the first wavelength conversion material 117 and the second wavelength conversion material 118 may be disposed above the third wavelength conversion material 219 and the third wavelength conversion material 219 may be disposed closer to the first light emitting device 111 than the first wavelength conversion material 117 and the second wavelength conversion material 118, in which the first wavelength conversion material 117 and the second wavelength conversion material 118 may be evenly mixed and dispersed therein. The third wavelength conversion material 219, which converts light of a relatively long wavelength, may be disposed close to the light emitting device to reduce reabsorption of short wavelengths, thereby improving light conversion efficiency of the third wavelength conversion material 219. Conversely, the first wavelength conversion material 117 and the second wavelength conversion material 118 may be disposed below the third wavelength conversion material 219, the first wavelength conversion material 117 and the second wavelength conversion material 118 may be disposed closer to the first light emitting device 111 than the third wavelength conversion material 219, and a fraction of light converted by the first wavelength conversion material 117 and the second wavelength conversion material 118 may be converted again in the third wavelength conversion material 219, thereby enabling reduction in manufacturing costs through reduction in amount of the third wavelength conversion material 219 to be used. Furthermore, at least one of the first to third wavelength conversion materials 117, 118, 219 may be disposed only in one region of the first light emitting device 111, thereby enabling reduction in manufacturing costs through reduction in amount of the wavelength conversion material to be used. Furthermore, at least one of the first wavelength conversion material 117, the second wavelength conversion material 118, or the third wavelength conversion material 219 may not be in direct contact with the first light emitting device 111. By way of example, the first wavelength conversion material 117 may be disposed adjacent to the first light emitting device 111; the second or third wavelength conversion material 118 or 219 may be disposed spaced apart therefrom by the first light transmitting layer 116 on which the first wavelength conversion material 117 is disposed without direct contact with the first light emitting device 111, and damage to the first light emitting device 111 by a fluorescent material containing fluorine like the third wavelength conversion material 219 may be reduced, thereby improving reliability of the light emitting diode.

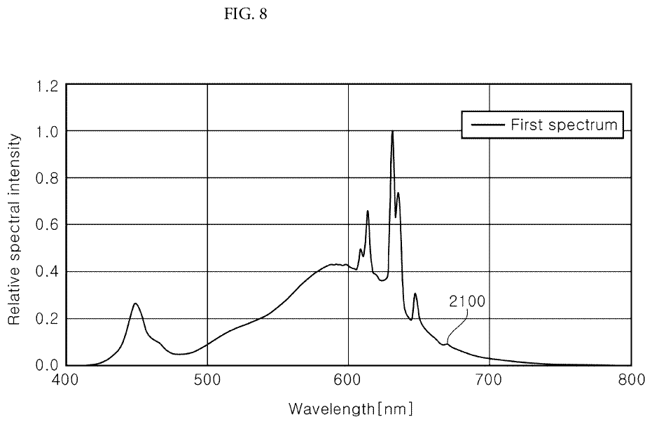

FIG. 8 to FIG. 10 are graphs depicting the effects of the light emitting apparatus 20 according to the second embodiment of the present disclosure.

FIG. 8 is a graph depicting a light emission spectrum of the first light emitter 210 of the light emitting apparatus 20 according to the second embodiment.

Referring to FIG. 8, a first spectrum 2100 of a first white light emitted from the first light emitter 210 has a high peak wavelength in the red wavelength band. In addition, the first spectrum 2100 may have a plurality of peak wavelengths in the red wavelength band. Further, the plurality of peak wavelengths in the red wavelength band may have a full width at half maximum of about 70 nm or less. Further, the plurality of peak wavelengths in the red wavelength band may have a full width at half maximum of about 50 nm or less.

The light emitting apparatus 20 according to the second embodiment further includes the third wavelength conversion material 219 in addition to the light emitting apparatus according to the first embodiment 10 (see FIG. 1).

Comparing FIG. 2, which shows the first spectrum 1100 of the light emitting apparatus 10 according to the first embodiment (FIG. 1), with FIG. 8, which shows the first spectrum 2100 of the light emitting apparatus 20 of the second embodiment, there is a difference in spectrum in the red wavelength band.

Comparing FIG. 2 with FIG. 8, the first spectrum 2100 shown in FIG. 8 has a higher peak wavelength than the first spectrum 1100 shown in FIG. 2 in the red wavelength band, and may have more peak wavelengths than the first spectrum 1100.

Thus, it can be seen that the high peak wavelength and the plurality of peak wavelengths appearing in the red wavelength band of the first spectrum 2100 emitted from the light emitting apparatus 20 according to the second embodiment are attributed to the effect of the third wavelength conversion material 219.

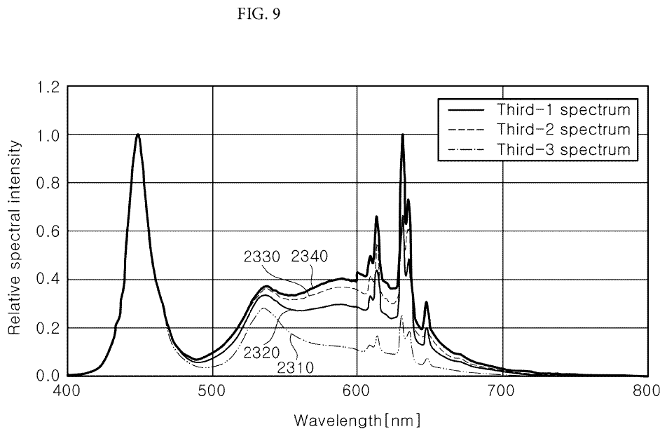

FIG. 9 is a graph depicting light emission spectra of the light emitting apparatus 200 according to the second embodiment depending on the ratio of the third wavelength conversion material 219 of the first light emitter 210.

More specifically, FIG. 9 illustrates a change of a third spectrum 2300 of the light emitting apparatus 200 when the ratio of the green and red wavelength bands to the blue wavelength band is increased.

In order of increasing ratio of the green and red wavelength bands to the blue wavelength band of the light emitting apparatus 200, the light emitting apparatus 200 emits light including a third-1 spectrum 2310, light including a third-2 spectrum 2320, light including a third-3 spectrum 2330, and light including a third-4 spectrum 2340.

Referring to FIG. 9, as the ratio of the green and red wavelength bands of the light emitting apparatus 200 increases, the luminous intensity of the peak wavelength in the green wavelength band and the luminous intensity of the peak wavelength in the red wavelength band of the third spectrum 2300 of a third white light of the light emitting apparatus 200 according to the second embodiment increase. Furthermore, as the ratio of the green and red wavelength bands of the light emitting apparatus 200 increases, the area of the green wavelength band and the area of the red wavelength band of the third spectrum 2300 increases, indicating that the intensity or quantity of a green light and a red light contained in the third white light increases.

In addition, the luminous intensity of the peak wavelength in the green wavelength band is less than the luminous intensity of the peak wavelength having the greatest luminous intensity in the red wavelength band. Further, the luminous intensity of the peak wavelength in the green wavelength band may be 35% or more, specifically 40% or more, of the luminous intensity of the peak wavelength having the greatest luminous intensity in the red wavelength band.

Further, a spectral area of the green wavelength band may be 50% or more, specifically 70% or more, of a spectral area of the red wavelength band. The color rendering index may be increased by supplementing an insufficient area of a green light of a typical light emitting apparatus to increase at least one of R2, R4, R5, or R6. Furthermore, a spectral area of the red wavelength band may be 70% or more, specifically 80% or more, of a spectral area of the blue wavelength band. The color rendering index may be increased by supplementing an insufficient area of a red light of a typical light emitting apparatus to increase at least one of R7 or R8.

Further, a difference between the luminous intensity of the peak wavelength in the green wavelength band and the luminous intensity of a valley wavelength having the lowest luminous intensity in the green wavelength band may be 3% or more. The first spectrum 1100 may have a clearer peak and valley in the green wavelength band than the second spectrum 1100. As a result, the light emitting apparatus 200 according to the second embodiment can improve the color reproduction rate of the third white light with a color gamut having a wide width.

FIG. 10 is a graph depicting the color rendering index (CRI) of the light emitting apparatus 200 according to the second embodiment depending upon the ratio of the green light (the green wavelength band) of the second light emitter and the ratio of the second red light of the first light emitter 210.

Referring to FIG. 10, a control group is a typical light emitting apparatus emitting a white light. Here, the typical light emitting apparatus includes a light emitting diode chip emitting a blue light and a phosphor layer including green phosphors and red phosphors. That is, the typical light emitting apparatus may correspond to the first light emitter 110 of the light emitting apparatus 100 according to the first embodiment (FIG. 1).

Referring to FIG. 10, the white light of the control group has a color rendering index Ra of 71. For the white light of the control group, R1, R4, R5, and R8 are significantly different from R2, R3, R6, and R7, respectively. In addition, the white light of the control group has a minimum value that is less than 50% of the maximum value among R1 to R8. An average Ra value may be increased by improving the color rendering index of at least one of R2, R3, R4, R6 or R5 through the green light of the second light emitting device 121 and by improving the color rendering index of at least one of R1, R7 or R8 through the third wavelength conversion material 219 of the first light emitting device.

The first white light of the first spectrum is the white light emitted from the first light emitter 210 of the light emitting apparatus 200 according to the second embodiment. Here, the first light emitter 210 according to the second embodiment includes the third wavelength conversion material 219 in addition to the control group.

Among R1 to R8 of the first white light of the first spectrum, the minimum value is 50% or more of the maximum value. That is, the difference between the maximum and minimum values among R1 to R8 is reduced for the first white light of the first spectrum compared to the control light. Furthermore, the first white light of the first spectrum is 79, which is greater than the Ra of the control light. From the comparison of the control group and the first white light of the first spectrum, it can be seen that the color rendering of the light emitting apparatus 200 of the second embodiment is improved by the third wavelength conversion material 219. In this case, the color rendering indexes of R3 to R5 may be 60 or more, and the difference between the color rendering indexes may be less than 30.

The white light of the light emitting apparatus 200 according to the second embodiment, that is, the third-1 white light of the third-1 spectrum to the third-4 white light of the third-4 spectrum, has a reduced difference between the maximum value and the minimum value among R1 to R8, as compared with the white light of the control group. Among R1 to R8, the minimum value is 50% or less of the maximum value for all of the third-1 white light of the third-1 spectrum to the third-4 white light of the third-4 spectrum.

In addition, it can be seen that the color rendering index Ra of the third-1 white light of the third-1 spectrum to the third-4 white light of the third-4 spectrum is greater than the Ra of the white light of the control group. Furthermore, Ra of the third-1 white light of the third-1 spectrum to the third-4 white light of the third-4 spectrum is greater than Ra of the first white light of the first light emitter 210 according to the second embodiment. Accordingly, it can be seen that the color rendering properties of the third-1 white light of the third-1 spectrum to the third-4 white light of the third-4 spectrum is improved compared with the color rendering properties of the control group and the first white light of the first spectrum. That is, the light emitting apparatus 200 according to the second embodiment further comprising the third wavelength conversion material 219 has better color rendering properties than a typical light emitting apparatus.

From FIG. 8 to FIG. 10, it can be seen that both the third wavelength conversion material 219 and the second light emitter according to the present disclosure can improve the color rendering properties of the light emitting apparatus 200.

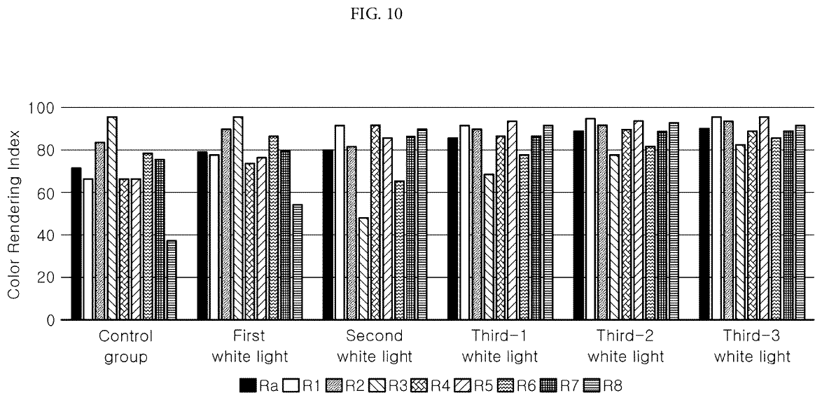

FIG. 11 is a view of a light emitting apparatus according to a third embodiment of the present disclosure.

Referring to FIG. 11, the light emitting apparatus 300 according to the third embodiment may include a substrate 150, a first light emitter 110, and a second light emitter 320.

The first light emitter 110 and the second light emitter are mounted on the substrate 150.

The first light emitter 110 may include a first light emitting device 111 and a first wavelength converter 115.

In addition, the second light emitter 320 may include a second light emitting device 121 and a second wavelength converter 315.

The substrate 150, the first light emitter 110, and the second light emitting device 121 of the light emitting apparatus 300 according to the third embodiment are the same as the substrate 150, the first light emitter 110, and the second light emitting device 121 of the light emitting apparatus 100 (see FIG. 1) according to the first embodiment.

According to this embodiment, the second wavelength converter 315 may cover the second light emitting device 121. Referring to FIG. 11, the second wavelength converter 315 may cover upper and side surfaces of the second light emitting device 121. That is, the second wavelength converter 315 may cover light emitting surfaces through which light emitted from the second light emitting device 121 is emitted. According to the present embodiment, the second wavelength converter 315 may have a different emission spectrum from the first wavelength converter 115.

The second wavelength converter 315 may include a second light transmitting layer 316 and a third wavelength conversion material 219.

The second light transmitting layer 316 may allow light emitted from the second light emitting device 121 to transmit therethrough. For example, the second light transmitting layer 316 may be formed of a transparent resin, such as an epoxy resin, a silicone resin, a fluorinated resin, or the like. Alternatively, the second light transmitting layer 316 may be formed of a light transmitting material, such as glass or ceramic. Alternatively, the second light transmitting layer 316 may be formed of a permeable material, such as fused silica, borosilicate, soda-lime glass, aluminosilicate, fluoro resins, or the like. Further, the second light transmitting layer 316 of the second wavelength converter 315 may be formed of the same material as or a different material from the first light transmitting layer 116 of the first wavelength converter 115.

The third wavelength conversion material 219 may be excited by light emitted from the second light emitting device 121 to emit light having a different emission spectrum or a different peak wavelength from the light emitted from the second light emitting device 121. For example, the third wavelength conversion material 219 may include at least one of quantum dots or phosphors that emit a red light. Here, the third wavelength conversion material 219 may emit light having a narrower full width at half maximum than the second wavelength conversion material 118. In addition, the third wavelength conversion material 219 may emit light having a different emission spectrum or a different peak wavelength from at least one of the first wavelength conversion material 117 or the second wavelength conversion material 118.

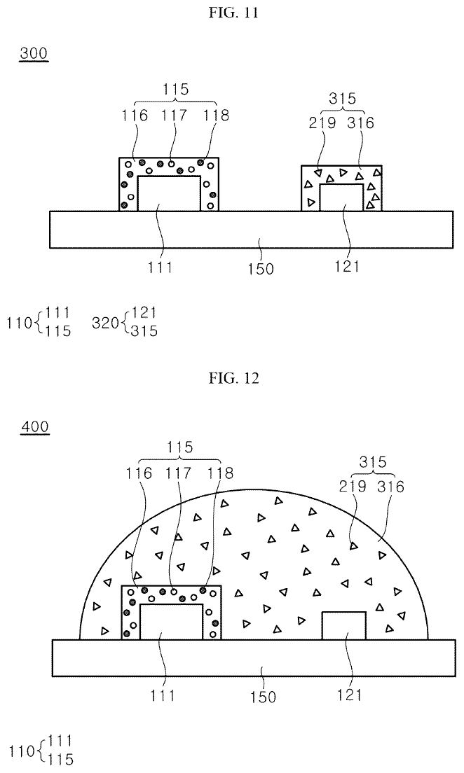

FIG. 12 is a view of a light emitting apparatus according to a fourth embodiment of the present disclosure.

The light emitting apparatus 400 according to the fourth embodiment may include a substrate 150, a first light emitter 110, a second light emitter, and a second wavelength converter 315.

The substrate 150, the first light emitter 110, and the second light emitter of the light emitting apparatus 400 according to the fourth embodiment are the same as the substrate 150, the first light emitter 110, and the second light emitter of the light emitting apparatus 100 (see FIG. 1) according to the first embodiment. Further, the second wavelength converter 315 of the light emitting apparatus 400 according to the fourth embodiment has the same features as the second wavelength converter 315 of the light emitting apparatus 300 according to the third embodiment except for the structure thereof.

The second wavelength converter 315 of the light emitting apparatus 400 according to the fourth embodiment may cover both the first light emitter 110 and the second light emitter on the substrate 150. Thus, the second wavelength converter 315 covers the upper and side surfaces of the first wavelength converter 115 of the first light emitter 110, which correspond to the light emitting surfaces thereof, and covers the light emitting surface of the second light emitting device 121.

The second wavelength converter 315 includes a second light transmitting layer 316 and a third wavelength conversion material 219, which are the same as the second light transmitting layer 316 and the third wavelength conversion material 219 described in the light emitting packages according to the third embodiment shown in FIG. 11.

The second wavelength converter 315 may be excited through absorption of fractions of light emitted from the second light emitting device 121 to emit light that has a different color or a different peak wavelength from the second light emitting device 121.

In addition, the second wavelength converter 315 may be excited through absorption of fractions of light emitted from the first wavelength converter 115 to emit light that has a different color, a different full width at half maximum, or a different peak wavelength from the first light emitting device 111, the first light conversion material 117, and the second light conversion material 118.

The light emitted from the first wavelength converter 115 includes a blue light of the first light emitting device, a green light of the first wavelength conversion material 117, and a first red light of the second wavelength conversion material 118. Here, the third wavelength conversion material 219 absorbs very little of the green light of the second wavelength conversion material 118 and the first red light of the second wavelength conversion material 118, and may be excited by absorbing the light emitted from the first light emitting device 111. Accordingly, even when the third wavelength conversion material 219 is added, the quantity of green light emitted from the first wavelength conversion material 117 and the quantity of the first red light emitted from the second wavelength conversion material 118 in the first light emitter 110 to the outside of the light emitting apparatus 400 can be reduced or variation of the ratio of the green light and the first red light can be minimized.

The light emitting apparatuses 300, 400 (see FIG. 11 and FIG. 12) according to the third and fourth embodiments have different structures from the light emitting apparatus according to the second embodiment 200 (see FIG. 7), and include the second light emitting device 121 and the third wavelength conversion material 219, thereby improving the color rendering properties as in the light emitting apparatus 200 (see FIG. 7) according to the second embodiment.

That is, light emitted from the light emitting apparatus 400 according to this embodiment includes light emitted through the second wavelength converter 315 covering the first wavelength converter 115. Here, the spectrum of light emitted from the first wavelength converter 115 of the first light emitter 110 and the spectrum of light emitted from the second wavelength converter 315 may have different shapes. The light emitting apparatus 300 according to this embodiment can improve the color rendering properties by supplementing light in a deficient color gamut of the first light emitter 110 using the second light emitting device 121 and the third wavelength conversion material 219, which have different emission spectra from the first light emitter 110.

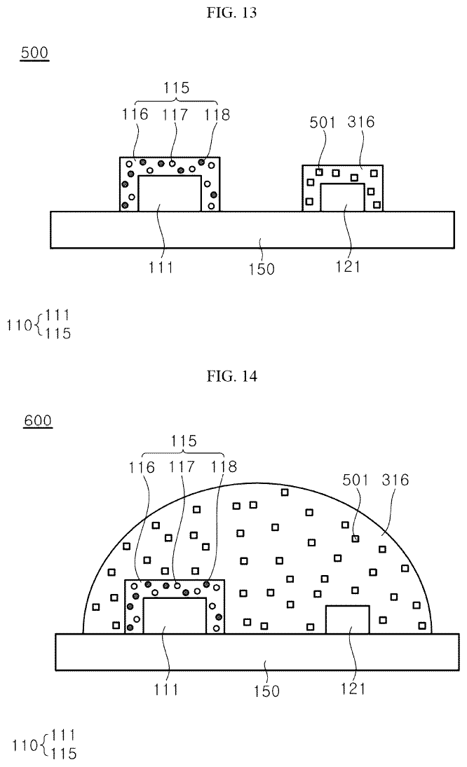

FIG. 13 is a view of a light emitting apparatus according to a fifth embodiment of the present disclosure. In addition, FIG. 14 is a view of a light emitting apparatus according to a sixth embodiment of the present disclosure.

The substrate 150, the first light emitter 110, and the second light emitter of the light emitting apparatuses 500, 600 according to the fifth and sixth embodiments are the same as the substrate 150, the first light emitter 110, and the second light emitter of the light emitting apparatus 100 (see FIG. 1) according to the first embodiment.

Referring to FIG. 13 and FIG. 14, each of the light emitting apparatuses 500, 600 may include a first light transmitting layer 116 and a second light transmitting layer 316. Referring to FIG. 13, the second light transmitting layer 316 covers the second light emitting device 121. In addition, referring to FIG. 14, the second light transmitting layer 316 covers both the first light emitter 110 and the second light emitting device 121, which corresponds to the second light emitter.

The second light transmitting layer 316 may be formed of a light transmitting material. The second light transmitting layer 316 may be formed of a transparent resin, such as an epoxy resin, a silicone resin, a fluorinated resin, or the like. Alternatively, the second light transmitting layer 316 may be formed of a light transmitting material, such as glass or ceramic. Alternatively, the second light transmitting layer 316 may be formed of a permeable material, such as fused silica, borosilicate, soda-lime glass, aluminosilicate, fluoro resins, or the like.

The second light transmitting layer 316 may include an optical material 501 dispersed therein. For example, the optical material 501 may include a diffusing agent. The diffusing agent may include barium oxide, barium titanate, silicon oxide, titanium oxide, aluminum oxide, melamine resin, guanamine resin, benzoguanamine resin, and the like. The diffusing agent applied to the embodiments is not limited thereto and may be any light diffusing agent known to those skilled in the art. The optical material 501 can spread light emitted from the first light emitter 110 and the second light emitting device 121 corresponding to the second light emitter such that the light can be evenly mixed.

According to the embodiments, a second light transmitting layer 526 containing the diffusing agent as the optical material 501 therein covers the second light emitter or both the first light emitter 110 and the second light emitter. Accordingly, light emitted from at least one of the first light emitter 110 or the second light emitter can be diffused while passing through the second light transmitting layer 316 to be emitted outside, thereby improving light emission uniformity of the light emitting apparatuses 500, 600.

In addition, the light emitting apparatuses 500, 600 may have two or more spectra by adjusting outputs of the two light emitting devices 111, 121. For example the light emitting apparatuses 500, 600 may have three or more spectra. By way of example, the light emitting apparatuses 500, 600 may have a first spectrum of light generated from the first light emitter 110, a second spectrum of light generated from the second light emitting device 121 corresponding to the second light emitter, or a third spectrum of light generated through simultaneous operation of the first light emitter 110 and the second light emitter.

Although the light emitting apparatuses 500, 600 shown in FIG. 13 and FIG. 14 include the optical material 501, such as a diffusing agent, dispersed in the second light transmitting layer 316, the optical material 501 may be omitted.

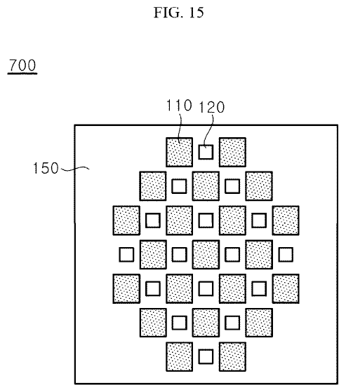

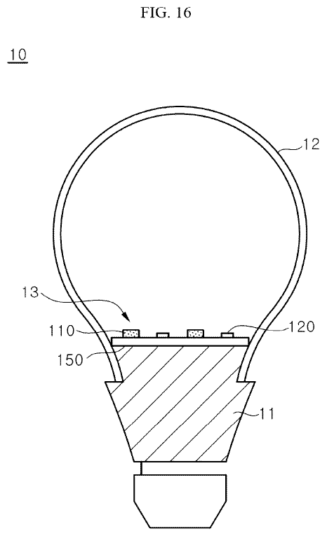

FIG. 15 is a view of a light emitting apparatus according to a seventh embodiment of the present disclosure.

The substrate 150, the first light emitter 110, and the second light emitter 120 of the light emitting apparatus 700 according to the seventh embodiment are the same as the substrate 150, the first light emitter 110, and the second light emitter of the light emitting apparatus 100 (see FIG. 1) according to the first embodiment.

Referring to FIG. 15, the light emitting apparatus 700 according to the seventh embodiment may include a plurality of first light emitters 110 and a plurality of second light emitters 120. Further, for the light emitting apparatus 700 according to the seventh embodiment, the number of first light emitters 110 is different from the number of second light emitters 120. However, it should be understood that embodiments of the present disclosure are not limited thereto. The light emitting apparatus 700 according to this embodiment may include a single second light emitter 120 or may include the same number of second light emitters 120 as the number of first light emitters 110. Further, the light emitting apparatus 700 according to this embodiment may include a plurality of configurations included in light emitting apparatuses of embodiments other than the first embodiment.

As such, the light emitting apparatus 700 including at least a first light emitter 110 and at least a second light emitter 120 may be realized through various combinations of the configurations of the light emitting apparatuses 100, 200, 300, 400, 500, 600 according to the first to sixth embodiments.

The substrate 150 of the light emitting apparatus 700 according to this embodiment may include a drive device or a drive circuit that controls drive power of the first light emitter 110 and the second light emitter 120.

Further, the light emitting apparatus 700 according to this embodiment may emit a third white light having predetermined color coordinates and a predetermined CRI by controlling the drive power while adjusting the emission ratio of the first light emitter 110 and the second light emitter 120. Here, the light emission ratio may be adjusted by adjusting a driving time or duty cycle of the first light emitter 110 and the second light emitter 120.

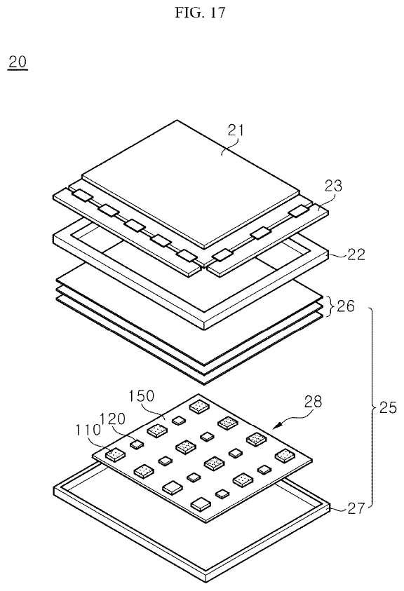

FIG. 16 is a view of a lighting apparatus including a light emitting apparatus according to an embodiment of the present disclosure.

A lighting apparatus 10 includes a body 11, a cover 12, and a light emitting apparatus 13.

The light emitting apparatus 13 is mounted on the body 450. The body 450 is provided therein with various configurations including devices, wiring, and the like for operation of the light emitting apparatus 13. The body 450 may also include a heat sink and a socket for connection to an external power source not shown in the drawings.

The cover 12 may be formed of a light transmitting material. The cover 12 may be coupled to the body 11 to cover the light emitting apparatus.

The light emitting apparatus 10 shown in FIG. 16 includes the light emitting apparatus 700 according to the seventh embodiment shown in FIG. 15. However, it should be understood that the light emitting apparatus 13 applied to the lighting apparatus 10 is not limited thereto. The light emitting apparatus 13 of the lighting apparatus 10 according to this embodiment may be realized by at least one of the light emitting apparatuses 100, 200, 300, 400, 500, 600, 700 according to the first to seventh embodiments, or may be realized in various ways through combination of the configurations thereof.

Although the lighting apparatus 10 shown in FIG. 16 is in the form of a light bulb, the light emitting apparatuses according to the embodiments of the present disclosure may be applied to various forms of lighting apparatus.

FIG. 17 is a view of a display apparatus including a light emitting apparatus according to an embodiment of the present disclosure.

According to this embodiment, the display apparatus 20 may include a display panel 21, a panel guide 22, and a backlight unit 25. Although not shown in the drawings, the display apparatus 20 may further include a top cover (not shown) that covers an upper periphery of the display panel 21 and is connected to the backlight unit 25.

The display panel 21 may include a thin film transistor substrate and a color filter substrate disposed to face each other and coupled to each other such that a uniform cell gap is maintained therebetween, and a liquid crystal layer interposed therebetween.

The display panel 21 is provided at a periphery thereof with a driving substrate 23 that supplies driving signals to gate lines and data lines.

The driving substrate 23 is electrically connected to the liquid crystal display panel 21 by a COF (Chip On Film). Here, the COF may be changed to a tape carrier package (TCP).

The backlight unit 25 may include optical sheets 26, a lower cover 27, and a light emitting apparatus 28.

The lower cover 27 has an open upper surface and may receive the optical sheets 26 and the light emitting apparatus 28 therein.

The optical sheets 26 include a diffusive sheet, a light collecting sheet, and a protective sheet. The optical sheets 26 may include one diffusive sheet and two light collecting sheets, or may include two diffusive sheets and one light collecting sheet.

In addition, the backlight unit 25 may further include a reflective sheet covering an upper surface of the substrate 150 of the light emitting apparatus 28 or disposed on a lower surface of the substrate 150. The reflective sheet may reflect light toward the optical sheets 26.

The light emitting apparatus 28 shown in FIG. 17 is a different form of the light emitting apparatus 700 (see FIG. 15) according to the seventh embodiment. However, it should be understood that the light emitting apparatus 28 applied to the display apparatus 20 is not limited thereto. The light emitting apparatus 28 of the display apparatus 20 according to this embodiment may be realized by at least one of the light emitting apparatuses 100, 200, 300, 400, 500, 600, 700 according to the first to seventh embodiments, or may be realized in various ways through combination of the configurations thereof.

As such, the light emitting apparatuses according to the first to seventh embodiments may be applied as light sources in a variety of devices, including lighting apparatuses and display apparatuses.

Although some embodiments have been described herein with reference to the accompanying drawings, it should be understood that the foregoing embodiments are provided for illustration only and are not to be in any way construed as limiting the technical idea of the present disclosure. The scope of the present disclosure should be defined by the appended claims and equivalents thereto.

What is claimed:

1. A light emitting apparatus comprising:
a substrate; and
a light emitting region disposed on the substrate and including a first light emitter and a second light emitter,
wherein light emitted from the first light emitter has a first spectrum, light emitted from the second light emitter has a second spectrum,
wherein the first light emitter includes a first light emitting device emitting light having a first peak wavelength and a first wavelength converter emitting a first light,
wherein the second light emitter includes a second light emitting device emitting the second spectrum,
wherein the first spectrum and the second spectrum has at least one different peak wavelength, and
wherein the light of the light emitting region has a third spectrum that is a mixtureof the first spectrum and the second spectrum.

2. The light emitting apparatus according to claim 1, wherein the first spectrum has peak wavelengths in a blue wavelength band and a red wavelength band, and the second spectrum has peak wavelengths in the blue wavelength band and a green wavelength band.

3. The light emitting apparatus according to claim 2, wherein the third spectrum has peak wavelengths in the blue wavelength band, the green wavelength band, and the red wavelength band.

4. The light emitting apparatus according to claim 2, wherein the first wavelength converter includes:
a first wavelength conversion material emitting light having a second peak wavelength; and
a second wavelength conversion material emitting a first red light.

5. The light emitting apparatus according to claim 4, wherein at least a portion of the first wavelength conversion material and the second wavelength conversion material is dispersed in a different region of the first light transmitting layer.

6. The light emitting apparatus according to claim 5, wherein the first wavelength converter further comprises a third wavelength conversion material emitting a second red light,
the second red light having a narrower full width at half maximum than the first red light.

7. The light emitting apparatus according to claim 6, wherein the third wavelength conversion material is dispersed in a region different from a region in which of the first wavelength conversion material or the second wavelength conversion material is dispersed

8. The light emitting apparatus according to claim 1, further including:
a second light transmitting layer covering both the first light emitter and the second light emitting device.

9. The light emitting apparatus according to claim 8, further including:
a second wavelength converter including the second light transmitting layer and a third wavelength conversion material dispersed in the second light transmitting layer and emitting a second red light,
wherein the second red light has a narrower full width at half maximum than the first red light.

10. The light emitting apparatus according to claim 4, wherein the second light emitter further comprises a second light transmitting layer covering the second light emitting device.

11. The light emitting apparatus according to claim 10, wherein the second light emitter further comprises the second light transmitting layer and a second wavelength converter comprising a third wavelength conversion material dispersed in the second light transmitting layer and emitting a second red light, and
wherein the second red light having a narrower full width at half maximum than the first red light.

12. The light emitting apparatus according to claim 1, wherein a color rendering index (Ra) of the third spectrum is higher than color rendering indexes of the first spectrum and the second spectrum.

13. A light emitting apparatus comprising:
a substrate; and
a light emitting region disposed on the substrate and including a plurality of first light emitters and a plurality of second light emitters,
wherein at least one of the first light emitters emits a first light, and includes a first light emitting device emitting light having a first peak wavelength and a first wavelength converter;
wherein at least one of the second light emitters includes a second light emitting device emitting light having a second spectrum; and
wherein the substrate includes a drive device or a drive circuit that configured to control drive power of the first light emitter and the second light emitter,
wherein the first wavelength converter comprises a first light transmitting layer formed of a light transmitting material and covering the first light emitting device, and at least a type of wavelength conversion material,
wherein the first spectrum and the second spectrum has at least one different peak wavelength,
wherein light of the light emitting region has a third spectrum as a mixture of the first spectrum and the second spectrum, and
wherein a color rendering index (Ra) of the third spectrum is higher than color rendering indexes of the first spectrum and the second spectrum.

14. The light emitting apparatus according to claim 13, wherein the first wavelength converter includes:
a first wavelength conversion material emitting light having a second peak wavelength; and
a second wavelength conversion material emitting a first red light.

15. The light emitting apparatus according to claim 14, wherein the first wavelength converter further includes a third wavelength conversion material having a second red light, and the second red light having a narrower full width at half maximum than the first red light.

16. The light emitting apparatus according to claim 15, further includes:
a second light transmitting layer covering the second light emitting device or covering both the first light emitter and the second light emitting device; and
a third wavelength conversion material dispersed in the second light transmitting layer and emitting the second red light,
wherein the second red light has a narrower full width at half maximum than the first red light.

17. A backlight unit comprising:
a light emitting apparatus;
a optical sheet disposed on the light emitting apparatus; and
a lower cover receiving the light emitting apparatus and the optical sheet therein,
the light emitting apparatus comprising:
a substrate;
a first light emitter disposed on the substrate and emitting light having a first spectrum; and
a second light emitter disposed on the substrate and emitting light having a second spectrum,
wherein the first light emitter includes a first light emitting device emitting light having a first peak wavelength and a first wavelength converter emitting a first light,
wherein the second light emitter includes a second light emitting device emitting light having the second spectrum,
wherein the first wavelength converter includes a first light transmitting layer formed of a light transmitting material and covering the first light emitting device, and at least one of wavelength conversion materials, and
wherein the first spectrum and the second spectrum has at least one different peak wavelength,
wherein the light emitting apparatus emits light having a third spectrum as a mixture of the first spectrum and the second spectrum.

18. The backlight unit according to claim 17, wherein the first wavelength converter includes:
a first wavelength conversion material dispersed in the first light transmitting layer and emitting a green light; and
a second wavelength conversion material dispersed in the first light transmitting layer and emitting a first red light.

19. The backlight unit according to claim 18, wherein the first wavelength converter further includes a third wavelength conversion material dispersed in the first light transmitting layer and emitting a second red light, and
wherein the second red light having a narrower full width at half maximum than the first red light.

20. The backlight unit according to claim 19, further including:
a second light transmitting layer covering the second light emitting device or covering both the first light emitter and the second light emitting device; and
a third wavelength conversion material dispersed in the second light transmitting layer and emitting a second red light,
wherein the second red light has a narrower full width at half maximum than the first red light.
